(19) United States
(12) Patent Application Publication
(10) Pub. No.: US 2024/0104714 A1
(43) Pub. Date: Mar. 28, 2024

(54) CONSTRUCTION INSPECTION METHOD, APPARATUS, AND SYSTEM

(71) Applicant: DAIKIN INDUSTRIES, LTD., Osaka (JP)

(72) Inventors: Qi WANG, Osaka (JP); Lan JIANG, Osaka (JP); Quan GAN, Osaka (JP)

(21) Appl. No.: 18/533,228

(22) Filed: Dec. 8, 2023

Related U.S. Application Data
(63) Continuation of application No. PCT/JP2022/023473, filed on Jun. 10, 2022.

(30) Foreign Application Priority Data
Jun. 10, 2021 (CN) 202110650860.X

(51) Int. Cl. G06T 7/00; G01S 13/86; G01S 13/89; G06T 17/00; G06T 19/20

(52) U.S. Cl. CPC G06T 7/0006; G01S 13/865; G01S 13/867; G01S 13/89; G06T 7/001; G06T 17/00; G06T 19/20; G06T 2207/30184; G06T 2210/04; G06T 2210/56; G06T 2219/2004

(57) ABSTRACT

A construction inspection method includes establishing a first construction model based on detection data at a construction site, comparing the first construction model with a previously established second construction model based on construction design data to acquire a comparison result, confirming an inspection result of a construction in accordance with the comparison result, and sharing the inspection result with a user. A construction inspection apparatus includes a modeling unit that establishes a first construction model based on detection data at a construction site, a comparison unit that compares the first construction model with a previously established second construction model based on construction design data to acquire a comparison result, a confirmation unit that confirms an inspection result of a construction in accordance with the comparison result, and a sharing unit that shares the inspection result with a user. A construction inspection system includes the construction inspection apparatus.

### CROSS-REFERENCE TO RELATED APPLICATIONS

This is a continuation of International Application No. PCT/JP2022/023473 filed on Jun. 10, 2022, which claims priority to Chinese Patent Application No. 202110650860.X, filed on Jun. 10, 2021. The entire disclosures of these applications are incorporated by reference herein.

### BACKGROUND

### Technical Field

The present invention relates to a construction technical field and, in particular, to a construction inspection method, apparatus, and system.

### Background Art

With the development of urbanization and the improvement of modernization, various constructions have become huge in size and complicated, but the traceability of construction quality management with the low level of computerization has always become a shortboard of the industry. Further, for the inspection of constructions, manual inspection is usually performed, but its efficiency is low, and execution of unified standards is also not possible. In addition, when a typical operation is performed on the concealed construction during the construction, it is almost impossible to accurately determine the construction quality, and the inspection operation is inconvenient, and therefore, the construction period of the construction becomes long, and the construction quality cannot be secured.

In recent years, a technique of using a virtual building construction three-dimensional model for supporting construction quality management has appeared.

It should be noted that the introduction of the above technical background is merely provided to facilitate the understanding of those skilled in the art while helping to provide clearer and more complete descriptions of the technical solutions of the present invention. These technical solutions are merely described in the background of the present invention and should not be construed as being publicly known to those skilled in the art.

### SUMMARY

A first aspect of the embodiment of the present invention provides a construction inspection method including a step of establishing a first construction model based on detection data at a construction site, a step of comparing the first construction model with a previously established second construction model based on construction design data to acquire a comparison result, a step of confirming an inspection result of a construction in accordance with the comparison result, and a step of sharing the inspection result with a user.

### BRIEF DESCRIPTION OF THE DRAWINGS

Many aspects of the present invention may be better understood with reference to the following attached drawings. The members in the attached drawings are not illustrated for comparison, but merely illustrated to indicate the principles of the present invention. For the purpose of convenient representation and description of some parts according to the present invention, the parts corresponding to the accompanying drawings may be enlarged or reduced. The elements or feature information illustrated in one attached drawing or one embodiment according to the present invention may be combined with elements or feature information illustrated in one or more other attached drawings or embodiments. Moreover, in the attached drawings, similar reference numerals denote the corresponding members in some attached drawings and may denote the corresponding members used in more than one embodiment.

In the attached drawings,

FIG. 1 is a flow chart of a construction inspection method according to a first embodiment of the present invention.

FIG. 2 is a flow chart of a method for implementing Step 101 using a laser radar signal according to the first embodiment of the present invention.

FIG. 3 is a flow chart of a method for implementing Step 101 using an image signal according to the first embodiment of the present invention.

FIG. 4 is a schematic view of acquiring detection data by an AR device or an unmanned device according to the first embodiment of the present invention.

FIG. 5 is a flow chart of a method for implementing Step 101 using a ground penetrating radar signal according to the first embodiment of the present invention.

FIG. 6 is a schematic view of a method for model alignment according to the first embodiment of the present invention.

FIG. 7 is a schematic view of collisional verification between a first construction model and a second construction model according to the first embodiment of the present invention.

FIG. 8 is a schematic view of marking a component having a mismatch according to the first embodiment of the present invention.

FIG. 9 is a flow chart of a method for implementing Step 103 according to the first embodiment of the present invention.

FIG. 10 is a flow chart of a method for inspecting installation of an air conditioner according to the first embodiment of the present invention.

FIG. 11 is another flow chart of a method for inspecting installation of an air conditioner according to the first embodiment of the present invention.

FIG. 12 is a schematic view of a construction inspection apparatus according to a second embodiment of the present invention.

FIG. 13 is a structural diagram of a construction inspection system according to a third embodiment of the present invention.

### DETAILED DESCRIPTION OF EMBODIMENT(S)

Preferred embodiments of the present invention will be described below with reference to the drawings.

### FIRST EMBODIMENT

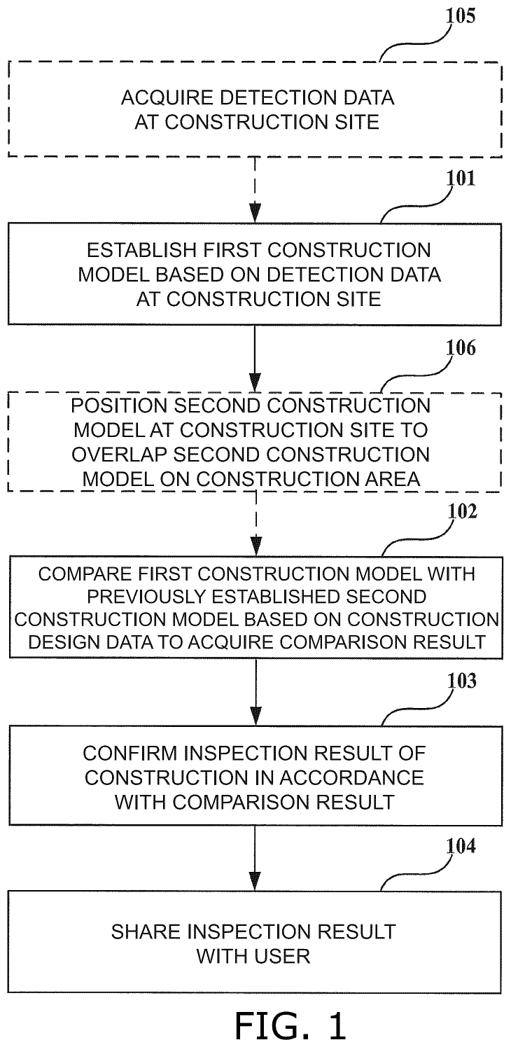

A first embodiment of the present invention provides a construction inspection method. FIG. 1 is a flow chart of the construction inspection method according to the first embodiment of the present invention. As illustrated in FIG. 1, the method includes the following steps:
Step 101: establishing a first construction model based on detection data at a construction site;
Step 102: comparing the first construction model with a previously established second construction model based on construction design data to acquire a comparison result;
Step 103: confirming an inspection result of a construction in accordance with the comparison result; and
Step 104: sharing the inspection result with a user.

Thus, the established model is compared with the design model based on the result actually detected at the site, and therefore the difference between the actually completed situation of the construction and the desired design plan may be accurately reflected, the accuracy of the inspection result may be high, and the inspection may also be performed according to a unified standard. In addition, as the two models are directly compared with each other, the processing process is simple, and the inspection efficiency is high. After the inspection result is obtained, the inspection result may also be shared with the user. Thus, the user at a location other than the site may also acquire the inspection result in a timely manner, which improves the inspection efficiency, enhances the convenience of inspection, saves time and effort, and improves the user experience.

According to an embodiment of the present invention, the construction site may also be, for example, an operation site of a construction such as inside a building or may also be an outdoor site.

According to an embodiment of the present invention, the construction inspection method may be used for inspection of various constructions, such as installation of air conditioners, constructions of buildings, or interior constructions.

According to an embodiment of the present invention, the construction inspection method may be applied to each stage during the construction, for example, intermediate inspection or completion inspection.

At Step 101, the first construction model is established based on detection data at the construction site.

According to an embodiment of the present invention, the first construction model may be used to simulate a currently completed construction site and all components that are included in the construction and are present at the construction site, and the information of each component may be stored or marked in the first construction model.

For example, when the construction is installation of an air conditioner, the construction may include at least one of components such as an indoor unit, an outdoor unit, a refrigerant pipeline, an electric wire pipeline, a condensation pipeline, and a control panel.

According to an embodiment of the present invention, the information of the component may be various types of information related to the component. For example, the information of the component may include at least one of the position, angle, model number, size, name, identifier, color, category, serial number, brand, material, and surface precision of the component.

According to an embodiment of the present invention, the detection data may be various types of detection data with which the first construction model may be established. Examples thereof may include laser radar signals, image signals, or ground penetrating radar signals.

For example, as illustrated in FIG. 1, the construction inspection method may further include the following steps:
Step 105: acquiring the detection data at the construction site.

According to an embodiment of the present invention, Step 105 is a selectable step in the construction inspection method. For example, the detection data at the construction site may be acquired before the construction inspection method is performed.

For example, the construction site is scanned by a laser radar sensor to acquire a returned laser radar signal, and the first construction model is established based on the returned laser radar signal.

According to an embodiment of the present invention, the laser radar sensor may be provided in an augmented reality (Augmented Reality, AR) device, may be provided in a virtual reality (Virtual Reality, VR) device, or may be provided in a mixed reality (Mixed Reality, MR) device.

Thus, the AR device, the VR device, or the MR device may acquire the detection signal to establish the first construction model and thus intuitively observes the first construction model and may facilitate subsequent model comparison and inspection.

According to an embodiment of the present invention, the AR device may be various types of AR devices. Examples thereof may include AR glasses, smart phones, tablets, or customized AR hand-held devices.

For example, a laser radar sensor attached to the AR glasses transmits a laser radar signal to scan the entire construction site and acquires the laser radar signal returned to the sensor.

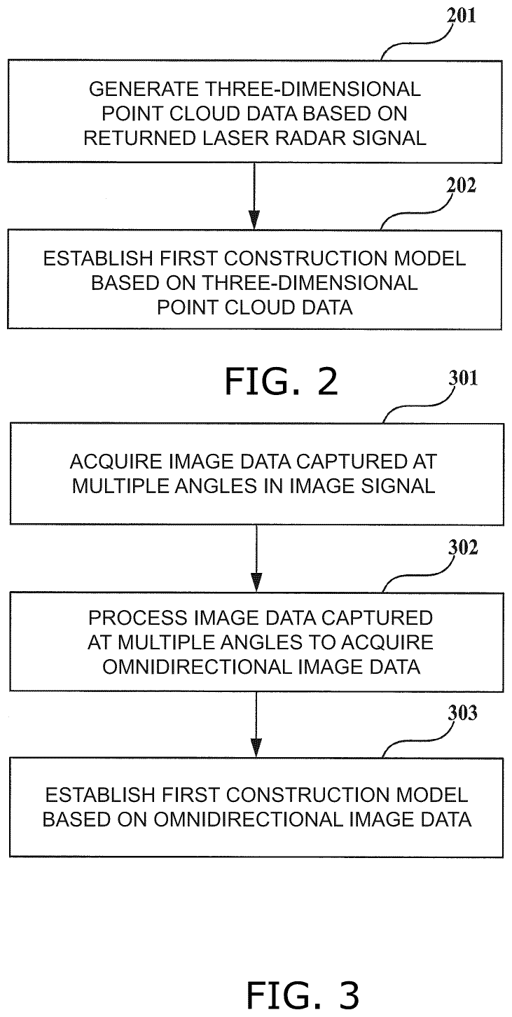

FIG. 2 is a flow chart of a method for implementing Step 101 using the laser radar signal according to the first embodiment of the present invention. As illustrated in FIG. 2, the method includes the following steps:
Step 201: generating three-dimensional point cloud data based on the returned laser radar signal; and
Step 202: establishing the first construction model based on the three-dimensional point cloud data.

For a specific modeling process, reference may be made to a related background art.

According to an embodiment of the present invention, for example, the construction site may be captured by an imaging device to acquire an image signal, and the first construction model may be established based on the image signal.

According to an embodiment of the present invention, the imaging device may be provided in an unmanned device or a robot. The construction site may be captured by the unmanned device or robot and thus captured at multiple angles and in all directions. Accordingly, the accuracy of the established first construction model is ensured.

FIG. 3 is a flow chart of a method for implementing Step 101 using an image signal according to the first embodiment of the present invention. As illustrated in FIG. 3, the method includes the following steps:
Step 301: acquiring image data captured at multiple angles in the image signal;
Step 302: processing the image data captured at the multiple angles to acquire omnidirectional image data; and
Step 303: establishing the first construction model based on the omnidirectional image data.

For example, the image signal is acquired by performing inclination capturing measurement by the unmanned device. For example, in the inclination capturing measurement, a ground object may be captured by five cameras mounted on the unmanned device from five directions, front, rear, left, right, and vertical directions, and then a series of processing such as geometric correction, balance adjustment, and multi-view video verification may be performed to acquire image data having omnidirectional information of the ground object, and then the first construction model may be modeled based on the image data. For a specific modeling process, reference may be made to a related background art.

FIG. 4 is a schematic view of acquiring detection data by an AR device or an unmanned device according to the first embodiment of the present invention. As illustrated in FIG. 4, at the construction site, a worker scans the entire construction site while wearing AR glasses to acquire a returned laser radar signal or captures images of the construction site in all directions by using an unmanned device equipped with an imaging device to acquire an image.

According to an embodiment of the present invention, for example, a ground penetrating radar (Ground Penetrating Radar, GPR) device may further transmit a high-frequency electromagnetic wave to the construction site to acquire a returned electromagnetic wave signal and establish the first construction model based on the returned electromagnetic wave signal. By establishing the first construction model with the ground penetrating radar signal, internal structures, which cannot be observed from outside, may be modeled. Examples thereof may include dark pipelines in a wall or underground, and various devices or structures closed by a ceiling.

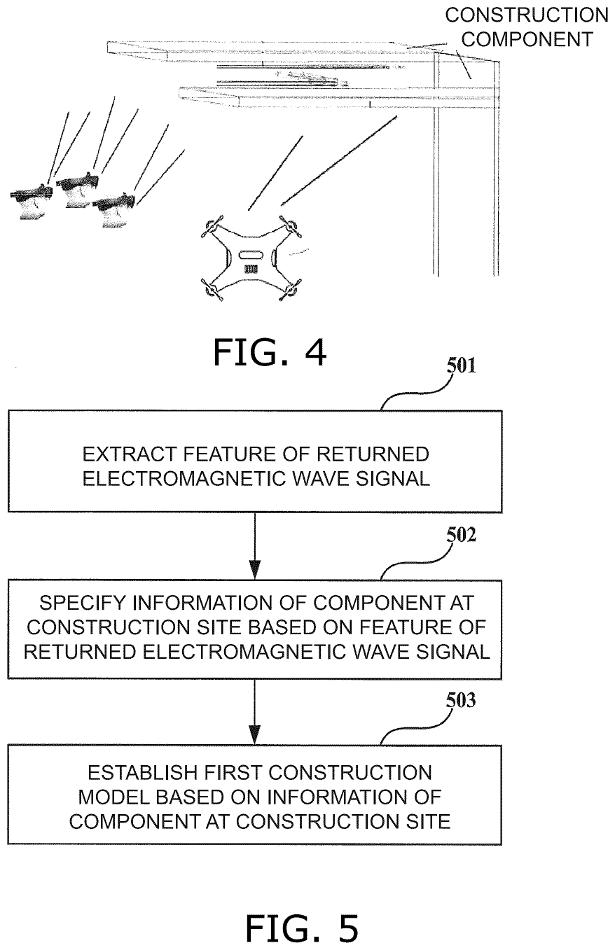

FIG. 5 is a flow chart of a method for implementing Step 101 using the ground penetrating radar signal according to the first embodiment of the present invention. As illustrated in FIG. 5, the method includes the following steps:
Step 501: extracting a feature of the returned electromagnetic wave signal;
Step 502: specifying information of a component at the construction site based on the feature of the returned electromagnetic wave signal; and
Step 503: establishing the first construction model based on the information of the component at the construction site.

For example, high-frequency electromagnetic waves are transmitted to the construction site by a transmitting antenna, and reflected electromagnetic waves are received by a receiving antenna, electromagnetic waves are reflected when they encounter a boundary surface having an electrical difference during propagation, and the spatial position, structure, form, embedding depth, and the like, of an internal component are inferred in accordance with the characteristics of the waveform, amplitude intensity, and temporal change of the received electromagnetic waves to acquire the information of the component, and the first construction model is established based on the information of the component at the construction site. For a specific modeling process, reference may be made to a background art.

According to an embodiment of the present invention, it is possible to determine which one of the laser radar signal, the image signal, and the ground penetrating radar signal is used to establish the first construction model according to an application situation.

For example, when the construction may be observed from outside, the laser radar signal or the image signal may be used to establish the first construction model; however, when it is difficult to observe the construction from outside or it is difficult to observe some components in the construction from outside, the ground penetrating radar signal may be used to establish the first construction model.

For example, for the installation of a central air conditioner, when the installation of the air conditioner is finished and there is no ceiling, the first construction model may be established by using the laser radar signal or the image signal, but when the installation of the air conditioner is finished and there is a ceiling, the first construction model may be established by using the ground penetrating radar signal.

According to an embodiment of the present invention, as described above, the information of the component in the first construction model may include at least one of the position, angle, model number, size, name, identifier, color, category, serial number, brand, material, and surface precision of the component. When it is difficult to directly acquire some of the information from the detection signal, it may be acquired in combination with other techniques.

For example, the image signal is input into a previously established AI model to be identified and determine the material of the component.

In addition, according to an embodiment of the present invention, various detection signals may be combined to establish the first construction model. For example, the laser radar signal and the ground penetrating radar signal may be combined to establish the first construction model.

According to an embodiment of the present invention, after the first construction model is established, in Step 102, the first construction model is compared with the previously established second construction model based on construction design data to acquire a comparison result.

According to an embodiment of the present invention, the second construction model is previously established based on the design data of the construction and may be various three-dimensional models. For example, the second construction model may be a building information model (Building Information Modeling, BIM).

According to an embodiment of the present invention, the second construction model may include information of all the components in the construction, and the information of the components may be various types of information related to the components. For example, the information of the component may include at least one of the position, angle, model number, size, name, identifier, color, category, serial number, brand, material, and surface precision of the component.

According to an embodiment of the present invention, the data of the second construction model may be previously stored in a terminal device used at the inspection site, such as an AR device.

Alternatively, the data of the second construction model may be acquired by the terminal device from a server of a cloud terminal.

According to an embodiment of the present invention, for example, as illustrated in FIG. 1, the following steps may be further included before Step 102:
Step 106: positioning the second construction model at the construction site to superimpose the second construction model on a construction area and displaying the second construction model by the augmented reality device. Furthermore, the first construction model and the comparison result may be displayed by the augmented reality device.

Accordingly, the second construction model matched with the position of the construction site, the established first construction model, and the comparison result are displayed on the site by the AR device, which is an augmented reality device, and thus the accuracy of inspection is improved, and the difference between the two models, i.e., the comparison result, may be intuitively observed.

According to an embodiment of the present invention, Step 106 is a selectable step.

According to an embodiment of the present invention, the second construction model may not be positioned at the construction site. In this way, the efficiency of the operation at the site is increased, and the flexibility is high.

According to an embodiment of the present invention, the positioning of the second construction model may be implemented in various ways.

For example, positioning may be performed with two location points at the construction area. The positioning operation with two points is simple and suitable for a wide range of personnel. By simply establishing two points on the ground, the second construction model and the construction area, e.g., a building body, may be positioned together.

Further, for example, positioning may be performed with a wall at the construction area. The positioning with the wall is positioning with three points, which may further increase the superimposition accuracy of the second construction model and the construction area and further improves the inspection accuracy.

Further, for example, the positioning may be performed by scanning a two-dimensional code installed at the construction area. For example, the two-dimensional code includes information of one wall at the construction area. Thus, the superimposition accuracy between the second construction model and the construction area may be further increased, and the accuracy of inspection is further improved. At the same time, the time required for point calibration is saved, and the accuracy of inspection is further improved.

Further, for example, positioning may be performed by a geographic information system (Geographic Information System, GIS).

According to an embodiment of the present invention, the construction inspection method may further include a step of matching a coordinate point of the first construction model to coincide with a coordinate point of the second construction model. Accordingly, the accuracy of the comparison result between the first construction model and the second construction model is increased, and the accuracy of inspection is further improved.

For example, when the first construction model is established, the coordinate point of the first construction model may be matched to coincide with the coordinate point of the second construction model. Accordingly, after the first construction model is established, it may be directly compared with the second construction model so that the processing process is simple and the inspection efficiency may be further improved.

Further, for example, when the first construction model is compared with the second construction model, matching may be performed such that the coordinate point of the first construction model coincides with the coordinate point of the second construction model. Accordingly, it is not necessary to perform alignment with respect to the model at the site, and thus labor saving may be achieved.

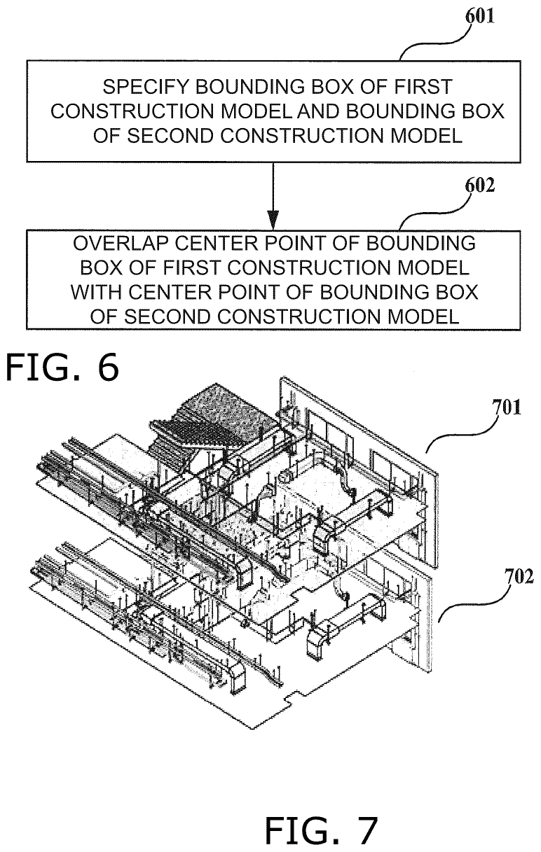

FIG. 6 is a schematic view of a method for model alignment according to the first embodiment of the present invention. As illustrated in FIG. 6, the method includes the following steps:
Step 601: specifying a bounding box of the first construction model and a bounding box of the second construction model; and
Step 602: overlapping a center point of the bounding box of the first construction model with a center point of the bounding box of the second construction model.

At Step 102, collisional verification between the first construction model and the second construction model may be performed to acquire the comparison result.

FIG. 7 is a schematic view of collisional verification between the first construction model and the second construction model according to the first embodiment of the present invention. As illustrated in FIG. 7, 701 indicates the first construction model, 702 indicates the second construction model, and the comparison result is acquired by performing collisional verification between the two models.

In Step 102, the information of all the components in the first construction model may be compared with the information of the corresponding components in the second construction model one by one to specify the component having a mismatch. For example, the ID of the component having a mismatch may be recorded. In addition, specific content of the mismatch may be recorded.

For example, the information of the component may include at least one of the position, angle, model number, size, name, identifier, color, category, serial number, brand, material, and surface precision of the component.

According to an embodiment of the present invention, the construction inspection method may further include a step of marking the component having the mismatch in the second construction model, and a step of displaying, by an augmented reality device, the second construction model in which the component having the mismatch is marked. Accordingly, it is possible to intuitively observe the component having a mismatch.

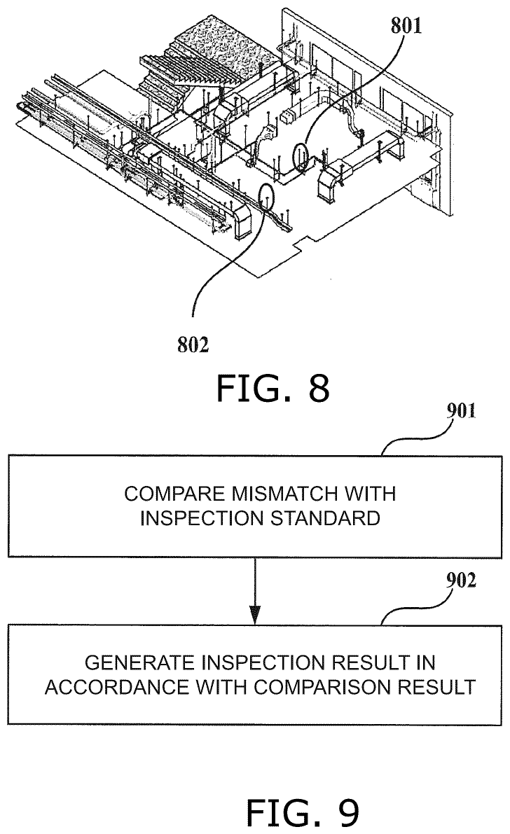

FIG. 8 is a schematic view of marking the component having a mismatch according to the first embodiment of the present invention. As illustrated in FIG. 8, in the second construction model 702, components 801 and 802 having mismatches are marked. Further, specific content of the mismatch may be displayed at the same time. For example, the degree of mismatch in position or angle may be displayed.

After acquiring the comparison result, in Step 103, the inspection result of the construction is confirmed in accordance with the comparison result.

FIG. 9 is a flow chart of a method for implementing Step 103 according to the first embodiment of the present invention. As illustrated in FIG. 9, the method includes the following steps:
Step 901: comparing the mismatch with an inspection standard; and
Step 902: generating the inspection result in accordance with the comparison result.

For example, when the position mismatch is greater than the position mismatch defined in the inspection standard, it is confirmed that the construction is defective, and when the position mismatch is less than or equal to the position mismatch defined in the inspection standard, it is confirmed that the construction is successful.

For various constructions, inspection standards in different industries or self-defined inspection standards by manufacturers may be used.

For example, for the installation of air conditioners, the inspection standard may include a pipeline and wiring inspection standard of air conditioners, and the inspection items are air conditioners, liquid pipes, gas pipes, supporting and lifting brackets, buckles, pipe joints, ducts, valves, and the like.

For example, the quality inspection items of the air conditioner may include a device model number, spatial position, horizontal angle, and vertical angle. Here, it is assumed that the position mismatch of the air conditioner is ±20 cm or less and the angle mismatch is ±10° or less. The liquid pipe and the gas pipe are requested to be provided with a thermal insulation material, the position mismatch of the liquid pipe and the gas pipe is ±30 cm or less, and the inclination angle is requested to meet the design requirement and not to exceed 10% beyond the range. The interval of the supporting and lifting bracket is requested to meet the design requirements and not to exceed 20% beyond the designed interval, and the inclination angle is requested not to exceed 10%. A shock absorbing pad is requested to be attached to a hanging leg. Buckles are requested to be rigid, and the number is requested to meet the design requirements. The quality inspection of the ducts is performed in accordance with the categories of the material, the machining process, and the system, and the quality inspection is requested to meet the design requirements, including the material, specification (radius and length), strength, and strictness of the ducts. The mounting position, height, and inlet and outlet directions of valves need to meet the design requirements, and the connection need to be secure and tight.

According to an embodiment of the present invention, the construction inspection method may further include a step of displaying an inspection result by a virtual reality (VR) device. For example, by transmitting the inspection result to the VR device and displaying the inspection result on the construction site or remotely by the VR device, the worker or the user may intuitively confirm the inspection result.

After the inspection result is acquired, in Step 104, the inspection result may be shared with the user. According to an embodiment of the present invention, the user is a user who is not at the construction site at the time of inspection.

For example, the inspection result may be transmitted to a server of the cloud terminal and shared with a specific user.

According to an embodiment of the present invention, the specific user is, for example, a client or another inspector who is not at the construction site.

In addition, according to an embodiment of the present invention, the second construction model may also be updated according to the inspection result.

According to an embodiment of the present invention, the construction inspection method may be implemented by local processing. That is, it is executed by a terminal device at the inspection site. For example, it may be executed by an AR device.

Alternatively, the construction inspection method may be implemented by processing using a cloud terminal. That is, it may be executed by a server of a cloud terminal.

For example, the terminal device at the inspection site may transmit the detection data to the server of the cloud terminal, and the server of the cloud terminal may execute each step of the construction inspection method.

The process in the cloud terminal and the process in the local terminal according to the construction inspection method will be described below in detail by taking the installation of the air conditioner as an example.

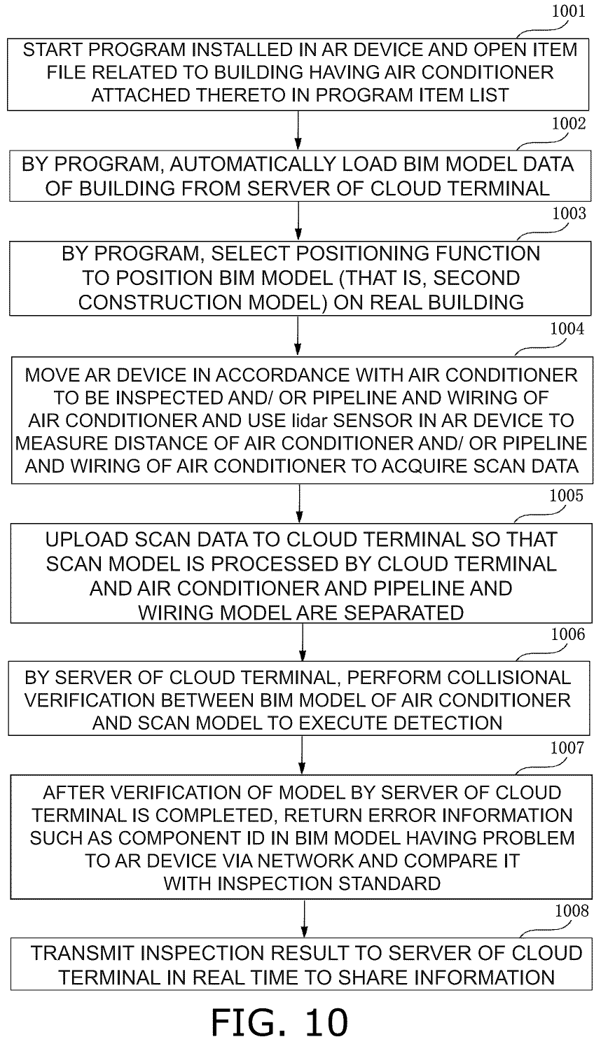

FIG. 10 is a flow chart of a method for inspecting the installation of an air conditioner according to the first embodiment of the present invention. As illustrated in FIG. 10, the method includes the following steps:
Step 1001: starting a program installed in the AR device and opening an item file related to the building having the air conditioner attached thereto in a program item list;
Step 1002: by the program, automatically loading BIM model data (e.g., the model type is .rvt or .fbx) of the building from the server of the cloud terminal, including the model and data of the building, the air conditioner, and the pipeline and wiring data of the air conditioner;
Step 1003: by the program, selecting a positioning function to position the BIM model (that is, the second construction model) on the real building. Accordingly, the effect of superimposition between the 3D virtual building and the real building is obtained. For example, the positioning may be performed by positioning with two points, positioning with a wall, or positioning by scanning a two-dimensional code.
Step 1004: moving the AR device in accordance with the air conditioner to be inspected and/or the pipeline and wiring of the air conditioner and using the lidar sensor in the AR device to measure the distance of the air conditioner and/or the pipeline and wiring of the air conditioner to acquire scan data;
Step 1005: uploading the scan data to the cloud terminal so that the scan model is processed by the cloud terminal and the air conditioner and the pipeline and wiring model are separated;
Step 1006: by the server of the cloud terminal, performing collisional verification between the BIM model of the air conditioner and the scan model to execute detection. When there is an inconsistent part between the two, the ID of the corresponding component in the BIM model is recorded, and the cause of inconsistency is also recorded, for example, the mismatch of the inclination angle, the mismatch of the position, or the misuse of the material.
Step 1007: after the verification of the model by the server of the cloud terminal is completed, returning error information such as the component ID in the BIM model having a problem to the AR device via a network and comparing it with the inspection standard. For those that do not meet the inspection standard, the AR device finds and marks the corresponding component locally from the component ID and marks the problem of construction and design difference in the model. Thus, the inspector may grasp mismatches in the contents of the construction and the contents of the design at a glance.
Step 1008: transmitting the inspection result to the server of the cloud terminal in real time to share information. Then, the owner or the construction team may view the inspection result in real time, which facilitates subsequent corrections for the inspection result and accelerates the inspection procedure.

Accordingly, the server of the cloud terminal mainly performs the process of inspection, which increases the processing speed and lowers the requirement on the processing capability of the hardware of the AR device.

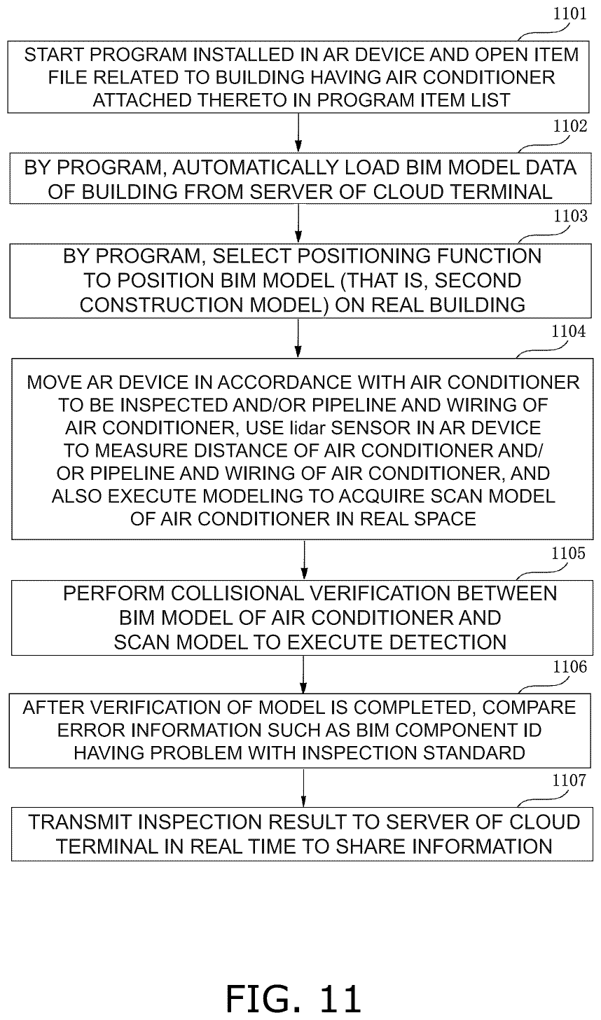

FIG. 11 is another flow chart of the method for inspecting the installation of the air conditioner according to the first embodiment of the present invention. As illustrated in FIG. 11, the method includes the following steps:
Step 1101: starting a program installed in the AR device and opening an item file related to the building having the air conditioner attached thereto in a program item list;
Step 1102: by the program, automatically loading BIM model data (e.g., the model type is .rvt or .fbx) of the building from the server of the cloud terminal, including the model and data of the building, the air conditioner, and the pipeline and wiring data of the air conditioner;
Step 1103: selecting a positioning function in the program to position the BIM model (that is, the second construction model) on the real building. Accordingly, the effect of superimposition between the 3D virtual building and the real building is obtained. For example, the positioning may be performed by positioning with two points, positioning with a wall, or positioning by scanning a two-dimensional code.
Step 1104: moving the AR device in accordance with the air conditioner to be inspected and/or the pipeline and wiring of the air conditioner, using the lidar sensor in the AR device to measure the distance of the air conditioner and/or the pipeline and wiring of the air conditioner, and also executing modeling to acquire and store the first construction model that is a scan model of the air conditioner in the real space;
Step 1105: performing collisional verification between the BIM model of the air conditioner and the scan model to execute detection. When there is an inconsistent part between the two, the ID of the corresponding component in the BIM model is recorded, and the cause of inconsistency is also recorded, for example, the mismatch of the inclination angle, the mismatch of the position, or the misuse of the material.
Step 1106: after the verification of the model is completed, comparing the error information such as the BIM component ID having a problem with the inspection standard. For those that do not meet the inspection standard, the AR device finds and marks the corresponding component locally from the component ID and marks the problem of construction and design difference in the model. Thus, the inspector may grasp mismatches in the contents of the construction and the contents of the design at a glance.
Step 1107: transmitting the inspection result to the server of the cloud terminal in real time to share information. Then, the owner or the construction team may view the inspection result in real time, which facilitates subsequent corrections for the inspection result and accelerates the inspection procedure.

Accordingly, the process of inspection by the local terminal device is mainly performed, which may be applied to various network states.

As may be understood from the above embodiment, the first construction model is established at the construction site based on the detection data at the site, the first construction model is compared with the previously established second construction model based on the design data, and the inspection result is confirmed in accordance with the comparison result so that the model established based on the result actually detected at the site is compared with the design model, and therefore it is possible to accurately reflect the difference between the actually completed situation of the construction and the desired design plan, the inspection result may be highly accurate, and the inspection may also be performed according to a unified standard. In addition, as the two models are directly compared with each other, the processing process is simple, and the inspection efficiency is high. After the inspection result is acquired, the inspection result may be shared with the user. Thus, the user at a location other than the site may also acquire the inspection result in a timely manner, which improves the inspection efficiency, enhances the convenience of inspection, saves time and effort, and improves the user experience.

### SECOND EMBODIMENT

A second embodiment of the present invention provides a construction inspection apparatus corresponding to the construction inspection method described in the first embodiment and, for the specific implementation thereof, reference may be made to the implementation of the method described in the first embodiment, and the descriptions may be omitted for the identical or related contents.

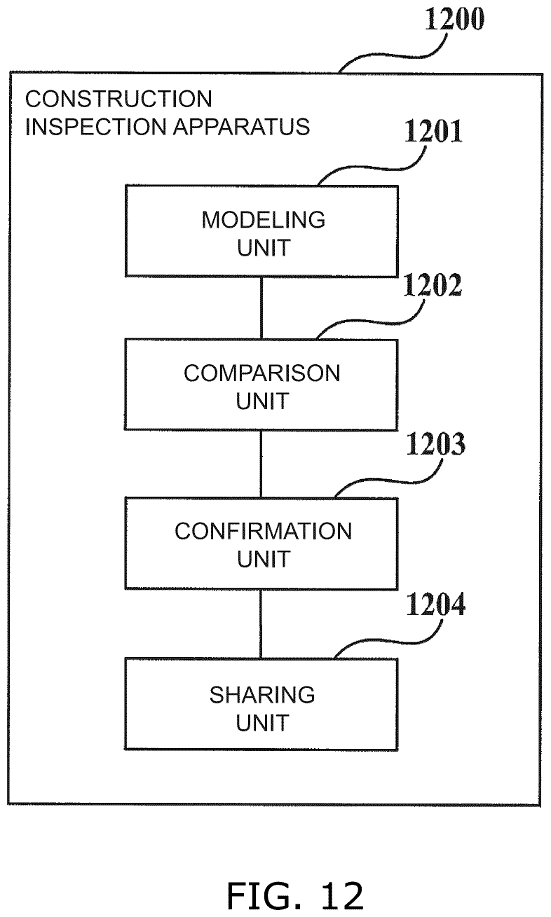

FIG. 12 is a schematic view of a construction inspection apparatus according to the second embodiment of the present invention. As illustrated in FIG. 12, a construction inspection apparatus 1200 includes
a modeling unit 1201 that establishes a first construction model based on detection data at the construction site,
a comparison unit 1202 that compares the first construction model with a previously established second construction model based on construction design data to acquire a comparison result,
a confirmation unit 1203 that confirms an inspection result of a construction in accordance with the comparison result, and
a sharing unit 1204 that shares the inspection result with the user.

According to an embodiment of the present invention, the construction inspection apparatus 1200 may be installed in a terminal device and/or a server of a cloud terminal.

According to an embodiment of the present invention, for the implementation of the function of each of the units, reference may be made to the contents of the related steps according to the first embodiment. The descriptions thereof may be omitted here.

As may be understood from the above embodiment, the first construction model is established at the construction site based on the detection data at the site, the first construction model is compared with the previously established second construction model based on the design data, and the inspection result is confirmed in accordance with the comparison result so that the model established based on the result actually detected at the site is compared with the design model, and therefore it is possible to accurately reflect the difference between the actually completed situation of the construction and the desired design plan, the inspection result may be highly accurate, and the inspection may also be performed according to a unified standard. In addition, as the two models are directly compared with each other, the processing process is simple, and the inspection efficiency is high. After the inspection result is acquired, the inspection result may be shared with the user. Thus, the user at a location other than the site may also acquire the inspection result in a timely manner, which improves the inspection efficiency, enhances the convenience of inspection, saves time and effort, and improves the user experience.

### THIRD EMBODIMENT

A third embodiment of the present invention provides a construction inspection system including the construction inspection apparatus according to the second embodiment and, for the specific implementation thereof, reference may be made to the implementation of the apparatus described in the second embodiment and the method described in the first embodiment, and the descriptions may be omitted for the identical or related contents.

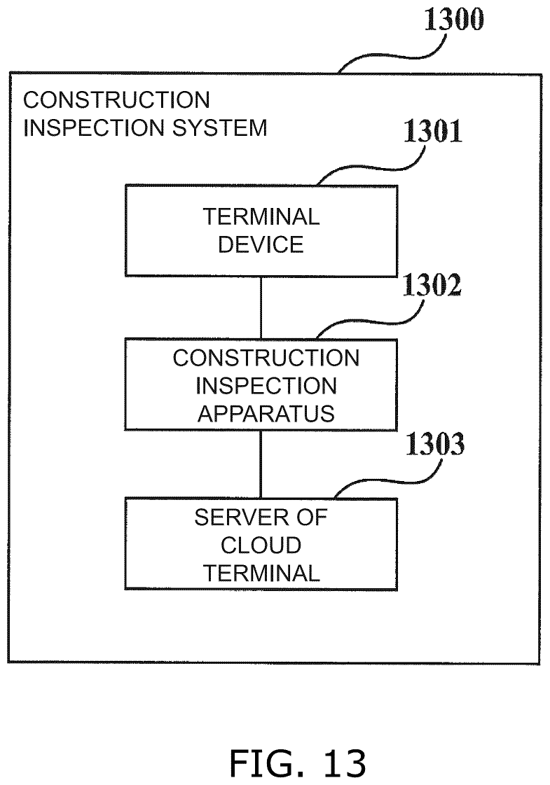

FIG. 13 is a structural diagram of a construction inspection system according to a third embodiment of the present invention. As illustrated in FIG. 13, a construction inspection system 1300 includes
a terminal device 1301 that acquires detection data at a construction site, and
a construction inspection apparatus 1302 that confirms an inspection result of a construction based on the detection data at the construction site and a previously established second construction model based on construction design data.

As illustrated in FIG. 13, the construction inspection system 1300 may further include
a server 1303 of a cloud terminal that stores data of the second construction model.

According to an embodiment of the present invention, the server 1303 may receive the inspection result of the construction and share it with a specific user.

According to an embodiment of the present invention, the construction inspection apparatus 1302 may be an individual device or may be integrated into the terminal device 1301 and/or the server 1303 of the cloud terminal.

According to an embodiment of the present invention, for the specific structure and function of the construction inspection apparatus 1302, reference may be made to the apparatus described in the second embodiment and the method described in the first embodiment, and the descriptions may be omitted here.

As may be understood from the above embodiment, the first construction model is established at the construction site based on the detection data at the site, the first construction model is compared with the previously established second construction model based on the design data, and the inspection result is confirmed in accordance with the comparison result so that the model established based on the result actually detected at the site is compared with the design model, and therefore it is possible to accurately reflect the difference between the actually completed situation of the construction and the desired design plan, the inspection result may be highly accurate, and the inspection may also be performed according to a unified standard. In addition, as the two models are directly compared with each other, the processing process is simple, and the inspection efficiency is high. After the inspection result is acquired, the inspection result may be shared with the user. Thus, the user at a location other than the site may also acquire the inspection result in a timely manner, which improves the inspection efficiency, enhances the convenience of inspection, saves time and effort, and improves the user experience.

The above apparatus and method according to the embodiments of the present invention may be implemented by hardware or may be implemented by a combination of hardware and software. The present invention relates to a computer-readable program below. When the program is executed by a logic unit, the logic unit may implement the above devices or components or implement the above various methods or steps.

An embodiment of the present invention relates to a storage medium that stores the above program, such as a hard disk, a magnetic disk, an optical disk, a DVD, or a flash memory.

It should be noted that, on the premise that the limitation of each step according to the present solution does not affect the implementation of the specific solution, the sequence of the steps is not limited, and the steps described above may be executed first, or may be executed later, or may be executed simultaneously. Any implementation of the present solution should be regarded as falling within the protection scope of the present application.

The present invention has been described above with reference to specific embodiments. However, it should be understood by those skilled in the art that these descriptions are merely exemplary and are not intended to limit the protection scope of the present invention. Based on the spirit and principle of the present invention, those skilled in the art may make various changes and modifications to the present invention, and these changes and modifications also fall within the scope of the present invention.

### Feature

With the development of urbanization and the improvement of modernization, various constructions have become huge in size and complicated, but the traceability of construction quality management with the low level of computerization has always become a shortboard of the industry. Further, for the inspection of constructions, manual inspection is usually performed, but its efficiency is low, and execution of unified standards is also not possible. In addition, when a typical operation is performed on the concealed construction during the construction, it is almost impossible to accurately determine the construction quality, and the inspection operation is inconvenient, and therefore, the construction period of the construction becomes long, and the construction quality cannot be secured.

In recent years, a technique of using a virtual building construction three-dimensional model for supporting construction quality management has appeared.

It should be noted that the introduction of the above technical background is merely provided to facilitate the understanding of those skilled in the art while helping to provide clearer and more complete descriptions of the technical solutions of the present invention. These technical solutions are merely described in the background of the present invention and should not be construed as being publicly known to those skilled in the art.

However, the inventor has found that the manual inspection method has low efficiency and poor accuracy, which cannot ensure the uniformity of the construction quality standard, and even when the building construction three-dimensional model is introduced, the inspection efficiency is still low due to its complicated processing process and its large calculation amount.

In order to solve at least one of the above problems, an embodiment of the present invention provides a construction inspection method, apparatus, and system, and at a construction site, a first construction model is established based on detection data at the site, the first construction model is compared with a previously established second construction model based on design data, and an inspection result is confirmed in accordance with a comparison result so that the model established based on the result actually detected at the site is compared with the design model, and therefore it is possible to accurately reflect the difference between the actually completed situation of the construction and the desired design plan, the inspection result may be highly accurate, and the inspection may also be performed according to a unified standard. In addition, as the two models are directly compared with each other, the processing process is simple, and the inspection efficiency is high. After the inspection result is acquired, the inspection result may be shared with the user. Thus, the user at a location other than the site may also acquire the inspection result in a timely manner, which improves the inspection efficiency, enhances the convenience of inspection, saves time and effort, and improves the user experience.

A first aspect of the embodiment of the present invention provides a construction inspection method including a step of establishing a first construction model based on detection data at a construction site, a step of comparing the first construction model with a previously established second construction model based on construction design data to acquire a comparison result, a step of confirming an inspection result of a construction in accordance with the comparison result, and a step of sharing the inspection result with a user.

A second aspect of the embodiment of the present invention provides a construction inspection apparatus including a modeling unit that establishes a first construction model based on detection data at a construction site, a comparison unit that compares the first construction model with a previously established second construction model based on construction design data to acquire a comparison result, a confirmation unit that confirms an inspection result of a construction in accordance with the comparison result, and a sharing unit that shares the inspection result with a user.

A third aspect of the embodiment of the present invention provides a construction inspection system including a terminal device that acquires detection data at a construction site, and the construction inspection apparatus according to the second aspect of the embodiment of the present invention that confirms an inspection result of a construction based on the detection data at the construction site and a previously established second construction model based on construction design data.

One of the advantages of the embodiment of the present invention is as follows. At the construction site, the first construction model is established based on the detection data at the site, the first construction model is compared with the previously established second construction model based on the design data, and the inspection result is confirmed in accordance with the comparison result so that the model established based on the result actually detected at the site is compared with the design model, and therefore it is possible to accurately reflect the difference between the actually completed situation of the construction and the desired design plan, the inspection result may be highly accurate, and the inspection may also be performed according to a unified standard. In addition, as the two models are directly compared with each other, the processing process is simple, and the inspection efficiency is high. After the inspection result is acquired, the inspection result may be shared with the user. Thus, the user at a location other than the site may also acquire the inspection result in a timely manner, which improves the inspection efficiency, enhances the convenience of inspection, saves time and effort, and improves the user experience.

With reference to the following description and drawings, specific embodiments of the present invention are disclosed in detail, and forms in which the principles of the present invention are adopted are also illustrated. It should be understood that the scope of the embodiment of the present invention is not limited thereto. The embodiment of the present invention includes many changes, modifications, and equivalents within the spirit and scope of the appended claims.

The feature information described and illustrated with respect to one embodiment may be used in the same way or in a similar way in one or more other embodiments, in combination with the features of the other embodiments, or instead of the feature information of the other embodiments.

It should be emphasized that the term “comprise/include” is used in this specification to indicate the presence of feature information, body components, steps, or members but does not preclude the presence or addition of one or more other feature information, body components, steps, or members.

1. A construction inspection method comprising:
establishing a first construction model based on detection data at a construction site;
comparing the first construction model with a previously established second construction model based on construction design data to acquire a comparison result;
confirming an inspection result of a construction in accordance with the comparison result; and
sharing the inspection result with a user.

2. The construction inspection method according to claim 1, further comprising:
acquiring the detection data, the acquiring the detection data including one of scanning the construction site by a laser radar sensor to acquire a returned laser radar signal,
capturing the construction site by an imaging device to acquire an image signal, and
transmitting a high-frequency electromagnetic wave to the construction site by a ground penetrating radar device to acquire a returned electromagnetic wave signal.

3. The construction inspection method according to claim 2, wherein at least one of
the laser radar sensor is provided in an augmented reality device, and
the imaging device is provided in an unmanned device or a robot.

4. The construction inspection method according to claim 2, wherein
the establishing the first construction model based on the detection data at the construction site includes
generating three-dimensional point cloud data based on the returned laser radar signal, and
establishing the first construction model based on the three-dimensional point cloud data.

5. The construction inspection method according to claim 2, wherein
the establishing the first construction model based on the detection data at the construction site includes
acquiring image data captured at multiple angles in the image signal,
processing the image data captured at the multiple angles to acquire omnidirectional image data, and
establishing the first construction model based on the omnidirectional image data.

6. The construction inspection method according to claim 2, wherein
the establishing the first construction model based on the detection data at the construction site includes
extracting a feature of the returned electromagnetic wave signal,
specifying information of a component at the construction site based on the feature of the returned electromagnetic wave signal, and
establishing the first construction model based on the information of the component at the construction site.

7. The construction inspection method according to claim 1, further comprising:
before comparing the first construction model with the second construction model,
positioning the second construction model at the construction site to superimpose the second construction model on a construction area and
displaying the second construction model by an augmented reality device.

8. The construction inspection method according to claim 7, further comprising:
displaying the first construction model and the comparison result by the augmented reality device.

9. The construction inspection method according to claim 7, wherein
the positioning the second construction model at the construction site includes one of
positioning with two location points at the construction area,
positioning with a wall at the construction area, and
positioning by scanning a two-dimensional code installed at the construction area.

10. The construction inspection method according to claim 1, further comprising:
matching a coordinate point of the first construction model to coincide with a coordinate point of the second construction model.

11. The construction inspection method according to claim 10, wherein
the matching the coordinate point of the first construction model to coincide with the coordinate point of the second construction model includes one of
before establishing the first construction model, matching the coordinate point of the first construction model to coincide with the coordinate point of the second construction model, and
matching the coordinate point of the first construction model to coincide with the coordinate point of the second construction model when comparing the first construction model with the second construction model.

12. The construction inspection method according to claim 11, wherein
the matching the coordinate point of the first construction model to coincide with the coordinate point of the second construction model when comparing the first construction model with the second construction model includes
specifying a bounding box of the first construction model and a bounding box of the second construction model, and
overlapping a center point of the bounding box of the first construction model with a center point of the bounding box of the second construction model.

13. The construction inspection method according to claim 1, wherein
the comparing the first construction model with the previously established second construction model based on the construction design data to acquire the comparison result includes
performing collisional verification between the first construction model and the second construction model to acquire the comparison result.

14. The construction inspection method according to claim 1, wherein
the comparing the first construction model with the previously established second construction model based on the construction design data to acquire the comparison result includes
comparing information of all components in the first construction model with information of corresponding components in the second construction model one by one to specify a component having a mismatch.

15. The construction inspection method according to claim 14, wherein
the information of the component includes at least one of a position, angle, model number, size, name, identifier, color, category, serial number, brand, material, and surface precision of the component.

16. The construction inspection method according to claim 14, further comprising:
marking the component having the mismatch in the second construction model; and
displaying, by an augmented reality device, the second construction model in which the component having the mismatch is marked.

17. The construction inspection method according to claim 14, wherein
the confirming the inspection result of the construction in accordance with the comparison result includes
comparing the mismatch with an inspection standard, and
generating the inspection result in accordance with the comparison result.

18. The construction inspection method according to claim 1, further comprising:
displaying the inspection result by a virtual reality device.

19. A construction inspection apparatus comprising:
a modeling unit configured to establish a first construction model based on detection data at a construction site;
a comparison unit configured to compare the first construction model with a previously established second construction model based on construction design data to acquire a comparison result;
a confirmation unit configured to confirm an inspection result of a construction in accordance with the comparison result; and
a sharing unit configured to share the inspection result with a user.

20. A construction inspection system including the construction inspection apparatus according to claim 19, the construction inspection system further comprising:
a terminal device configured to acquire detection data at a construction site,
the construction inspection apparatus being configured to confirm an inspection result of a construction based on the detection data at the construction site and a previously established second construction model based on construction design data.
